(19) United States
(12) Patent Application Publication
(10) Pub. No.: US 2016/0113148 A1
(43) Pub. Date: Apr. 21, 2016

(54) COOLING DEVICE AND COOLED ELECTRICAL ASSEMBLY COMPRISING THE SAME

(71) Applicant: ABB Technology Oy, Helsinki (FI)

(72) Inventors: Jorma Manninen, Vantaa (FI); Timo Koivuluoma, Vantaa (FI)

(21) Appl. No.: 14/869,260

(22) Filed: Sep. 29, 2015

(30) Foreign Application Priority Data
Oct. 20, 2014 (EP) 14189488.1

(51) Int. Cl. H05K 7/20; F25B 21/02

(52) U.S. Cl. CPC H05K 7/20145; F25B 21/02

(57) ABSTRACT

A cooling device comprising a first chamber (1), a second chamber (2) separated from the first chamber (1), heat exchanger means (4) adapted to transfer heat from the first chamber (1) to the second chamber (2), and fan means. The first chamber (1) comprises an inlet flow opening (12) and an outlet flow opening (14). The fan means is adapted to generate a first cooling medium flow (511) inside the first chamber (1) between the inlet flow opening (12) and the outlet flow opening (14) such that heat is transferred from the first cooling medium flow (511) into the heat exchanger means.

### FIELD OF THE INVENTION

The present invention relates to a cooling device and cooled electrical assembly comprising the cooling device.

An electric cabinet comprising one or more electrical apparatuses typically requires cooling. Providing an appropriate cooling may be difficult for example in situations where new apparatuses are mounted into an electric cabinet which was already nearly full. It may be necessary to reorganize the electric cabinet in order to provide required cooling for all the apparatuses.

### BRIEF DESCRIPTION OF THE INVENTION

An object of the present invention is to provide a cooling device and cooled electrical assembly comprising the cooling device so as to alleviate the above mentioned problem. The objects of the invention are achieved by a cooling device and cooled electrical assembly which are characterized by what is stated in the independent claims. The preferred embodiments of the invention are disclosed in the dependent claims.

The invention is based on the idea of providing a cooling device with a first chamber with an inlet flow opening and an outlet flow opening on the same side of the first chamber, a second chamber separated from the first chamber, heat exchanger means adapted to transfer heat from the first chamber to the second chamber, and fan means for generating a cooling medium flow inside the first chamber between the inlet flow opening and the outlet flow opening such that heat is transferred from the cooling medium into the heat exchanger means.

The cooling device of the invention is easy to clean and maintain, and enables isolating a device chamber containing an electrical apparatus from ambient air such that the device chamber is adapted to exchange cooling medium exclusively with the cooling device. In an embodiment a cooling device according to present invention is adapted to be retrofitted on a wall of an existing electric cabinet.

### BRIEF DESCRIPTION OF THE DRAWINGS

In the following the invention will be described in greater detail by means of preferred embodiments with reference to the attached drawings, in which

FIG. 1 shows a cooling device according to an embodiment of the invention;

FIGS. 2A-2C show three alternatives for connecting a thermoelectric cooling element to heat exchanger means of a cooling device; and

FIG. 3 shows a cooled electrical assembly comprising the cooling device of FIG. 1.

### DETAILED DESCRIPTION OF THE INVENTION

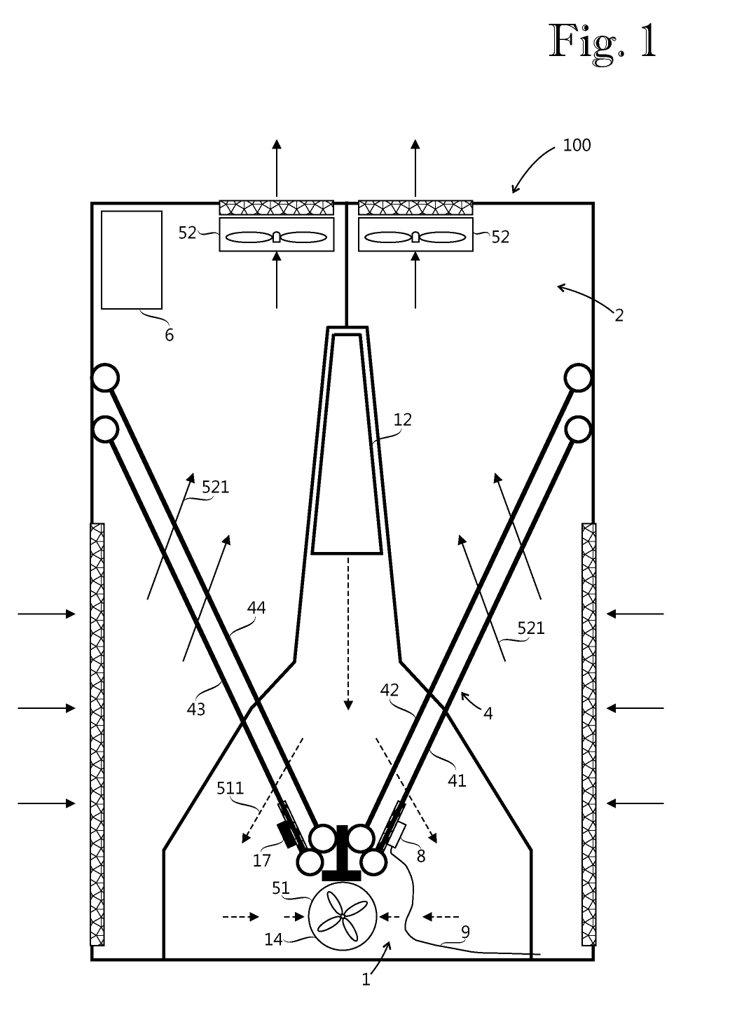

FIG. 1 shows a cooling device 100 comprising a first chamber 1, a second chamber 2, heat exchanger means 4, fan means, control means 6, a thermoelectric cooling element 8, pipe means 9 and a heating element 17. The second chamber 2 is separated from the first chamber 1 and adapted to be in contact with ambient air. Separation of the first chamber 1 and second chamber 2 prevents dirt from entering the first chamber 1 from the second chamber 2. The heat exchanger means 4 comprises a first heat exchanger 41, a second heat exchanger 42, a third heat exchanger 43 and a fourth heat exchanger 44. A first end of each of the four heat exchangers is located in the first chamber 1, and a second end of each of the four heat exchangers is located in the second chamber 2. The heat exchanger means 4 is adapted to transfer heat from the first chamber 1 to the second chamber 2.

Each of the four heat exchangers 41 to 44 is a compact thermosyphon heat exchanger. A compact thermosyphon heat exchanger is a passive heat exchanger based on natural convection. Said first end of each of the four heat exchangers is a lower end thereof, and said second end of each of the four heat exchangers is an upper end thereof. In an alternative embodiment heat exchanger means comprises at least one heat exchanger. Said at least one heat exchanger may comprise a compact thermosyphon heat exchanger and/or a heat exchanger of another type.

Each heat exchanger 41 to 44 is in an inclined position extending in an angle of inclination relative to horizontal direction. In the embodiment of FIG. 1 the angle of inclination is approximately 65°. In an alternative embodiment including one or more compact thermosyphon heat exchangers the angle of inclination may be between 35° and 90°. In an embodiment including a heat exchanger which is not a compact thermosyphon heat exchanger the heat exchanger may extend at any angle especially if the heat exchanger is based on a forced cooling medium flow inside the heat exchanger. In a further embodiment heat exchanger means comprises at least one curved heat exchanger. Using curved heat exchangers allows more freedom in cooling device design.

The heat exchanger means 4 divides the first chamber 1 into an upper section and a lower section. To be more specific, the first ends of the heat exchangers 41 to 44 divide the first chamber 1 into an upper section and a lower section. The first chamber 1 comprises an inlet flow opening 12 in the upper section of the first chamber 1, and an outlet flow opening 14 in the lower section of the first chamber 1. Inside the first chamber 1 the only route for a cooling medium flow from the inlet flow opening 12 to the outlet flow opening 14 passes through the first ends of the heat exchangers 41 to 44. Besides the inlet flow opening 12 and the outlet flow opening 14 there are no openings in the first chamber 1 providing access between an interior and an exterior of the first chamber 1.

The inlet flow opening 12 and the outlet flow opening 14 are located on the same side of the first chamber 1 on a connection wall of the cooling device 100. The cooling device 100 is adapted to be connected to a device chamber containing a heat generating apparatus such that the connection wall of the cooling device 100 faces the device chamber. In an alternative embodiment inlet flow opening and outlet flow opening are located on different sides of a first chamber. Such a design is useful when an electric cabinet comprising a device chamber has a stepped profile.

The fan means comprises a first fan 51 and two second fans 52. The control means 6 is adapted to control the fan means in order to adjust cooling power of the cooling device. The control means 6 is also adapted to control the thermoelectric cooling element 8 and the heating element 17. The control means 6 is adapted to receive measurement data from one or more humidity sensors and one or more temperature sensors which are not depicted in FIG. 1.

In an alternative embodiment control means comprises at least one thermostat adapted to control fan means based on temperature present in a first chamber of cooling device. In a further alternative embodiment a cooling device does not comprise control means. Such a simple embodiment is feasible in steady environments, for example when a cooling device is located indoors.

The first fan 51 is adapted to generate a first cooling medium flow 511 inside the first chamber 1 between the inlet flow opening 12 and the outlet flow opening 14 through the first ends of the heat exchangers 41 to 44. The first fan 51 is located in the first chamber 1. In an alternative embodiment fan means comprises a plurality of first fans adapted to generate a first cooling medium flow inside the first chamber between the inlet flow opening and the outlet flow opening through first end of at least one heat exchanger.

The second chamber 2 comprises two sub chambers separated from each other. Each of the sub chambers is divided into an upper section and a lower section by the heat exchanger means 4. One of the sub chambers is divided into an upper section and a lower section by the second ends of the heat exchangers 41 and 42. The other sub chamber is divided into an upper section and a lower section by the second ends of the heat exchangers 43 and 44.

Each sub chamber of the second chamber 2 comprises a second fan 52 adapted to generate a second cooling medium flow 521 through the second ends of corresponding heat exchangers. One second fan 52 is adapted to generate a second cooling medium flow 521 through the second ends of the heat exchangers 41 and 42. Another second fan 52 is adapted to generate a second cooling medium flow 521 through the second ends of the heat exchangers 43 and 44.

Each second cooling medium flow 521 enters a lower section of corresponding sub chamber through an inlet filter, passes through the second ends of corresponding heat exchangers, and exits the sub chamber through an outlet filter. The inlet filter and the outlet filter are adapted to keep the second chamber clean thereby maintaining cooling power of the heat exchangers. In an embodiment inlet filter and the outlet filter are coarse filters.

Operation of each sub chamber of the second chamber 2 is independent from operation of the other sub chamber. Malfunction of one second fan 52 decreases cooling power of the cooling device less than 50% because the other second fan 52 still operates with full power and there is natural convection present in the sub chamber with the malfunctioning fan. This also means that during maintenance it is possible to turn of the second fans one at the time while the other is operating. After one second fan is turned off a sub chamber containing the one second fan may be cleaned. Cleaning a sub chamber may include cleaning each second end of heat exchanger located in the sub chamber.

Then the one second fan is restarted and the other second fan is turned off for cleaning procedure. Consequently the cooling device provides at least 50% cooling power even during cleaning of the second chamber 2.

In an alternative embodiment a second chamber does not comprise any second fans. In such an alternative embodiment a natural convection provides a cooling medium flow in the second chamber. It is also possible to provide the second chamber as an undivided chamber. In a further alternative embodiment a second chamber is an open chamber with less walls than depicted in FIG. 1. In an embodiment where an environment of the cooling device is clean the second chamber does not need any walls except a wall separating the second chamber from the first chamber.

The thermoelectric cooling element 8 is located in the lower section of the first chamber 1. The thermoelectric cooling element 8 is in heat transfer connection with a first end of the first heat exchanger 41. The thermoelectric cooling element 8 is adapted to condense moisture from the first chamber 1. The pipe means 9 is adapted to carry water condensed by the thermoelectric cooling element 8 into the second chamber 2. In an alternative embodiment pipe means is adapted to carry water condensed by the thermoelectric cooling element out of the first chamber. The condensed water may be led out of the cooling device. In a further alternative embodiment pipe means may be omitted. Also, in an embodiment where moisture is not a problem the thermoelectric cooling element may be omitted.

The heating element 17 is adapted to heat the first chamber 1. The heating element 17 is in heat transfer connection with a first end of the third heat exchanger 43. In an alternative embodiment a cooling device does not comprise a heating element. A heating element may be omitted for example in embodiments where temperature is always above freezing point.

A heat transfer connection between a heating element and a first end of a heat exchanger transfers heat of the heating element effectively to a bypassing cooling medium flow. A heating element may comprise a resistor.

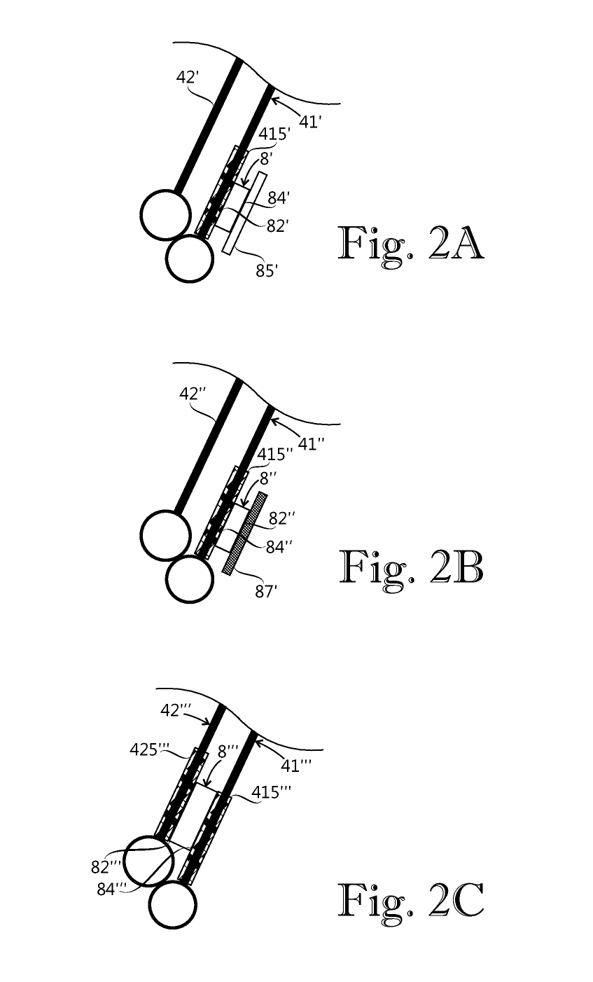

FIGS. 2A-2C show three alternatives for connecting a thermoelectric cooling element to heat exchanger means of a cooling device. FIG. 2A shows a thermoelectric cooling element 8′ having a hot side 82′ and a cold side 84′. The hot side 82′ is in heat transfer connection with a first end of a first heat exchanger 41′. The first end of the first heat exchanger 41′ is provided with a base plate 415′, and the hot side 82′ of the thermoelectric cooling element 8′ is in heat transfer connection with the base plate 415′. The base plate 415′ is adapted to increase contact area between the first end of the first heat exchanger 41′ and the hot side 82′ of the thermoelectric cooling element 8′. There is a water condensation plate 85′ connected to the cold side 84′ of the thermoelectric cooling element 8′. During operation of the cooling element 8′ water condenses on a surface of the water condensation plate 85′. The thermoelectric cooling element 8′ is positioned on an underside of the inclined cooling element 8′ such that water dripping from the water condensation plate 85′ does not drip on the first heat exchanger 41′ or on a second heat exchanger 42′ located on opposite side of the first heat exchanger 41′ relative to the thermoelectric cooling element 8′.

FIG. 2B shows a thermoelectric cooling element 8″ whose cold side 84″ is in heat transfer connection with a base plate 415″ of a first heat exchanger 41″. There is a heat sink 87″ connected to the hot side 82″ of the thermoelectric cooling element 8″.

FIG. 2C shows heat exchanger means comprising a first heat exchanger 41′″ and a second heat exchanger 42′″ adjacent the first heat exchanger 41′″. There is a thermoelectric cooling element 8′″ between the first heat exchanger 41′″ and the second heat exchanger 42′″. A cold side 84′″ of the thermoelectric cooling element 8′″ is in heat transfer connection with a base plate 415′″ of the first heat exchanger 41′″. A hot side 82′″ of the thermoelectric cooling element 8′″ is in heat transfer connection with a base plate 425′″ of the second heat exchanger 42′″.

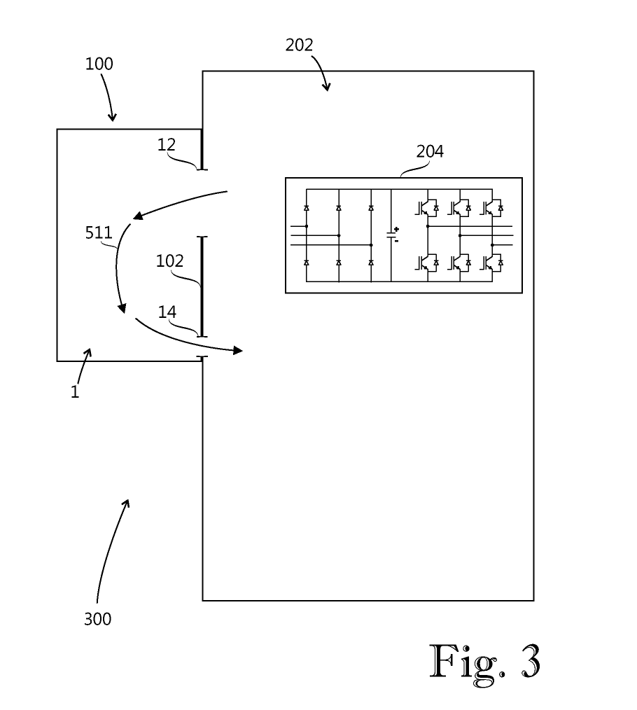

FIG. 3 shows a cooled electrical assembly 300 comprising the cooling device 100 of FIG. 1. The cooling device 100 is connected to a device chamber 202 containing a heat generating apparatus 204. A connection wall 102 of the cooling device 100 faces the device chamber 202. The connection wall 102 is a substantially planar wall for facilitating connection of the cooling device 100 to the device chamber 202. In an embodiment the heat generating apparatus comprises a frequency converter. In an alternative embodiment the heat generating apparatus comprises an inverter or some other electrical apparatus which requires cooling.

The device chamber 202 is isolated from ambient air such that the device chamber 202 is adapted to exchange cooling medium exclusively with the first chamber 1 of the cooling device 100. Therefore cooling medium circulating in the device chamber 202 is always clean.

It will be obvious to a person skilled in the art that the inventive concept can be implemented in various ways. The invention and its embodiments are not limited to the examples described above but may vary within the scope of the claims.

1. A cooling device comprising:
a first chamber;
a second chamber separated from the first chamber and adapted to be in contact with ambient air;
heat exchanger means comprising at least one heat exchanger, the heat exchanger means dividing the first chamber into an upper section and a lower section, a first end of each of the at least one heat exchanger being located in the first chamber, and a second end of each of the at least one heat exchanger being located in the second chamber, the heat exchanger means being adapted to transfer heat from the first chamber to the second chamber; and
fan means;
wherein the first chamber comprises an inlet flow opening in the upper section of the first chamber, and an outlet flow opening in the lower section of the first chamber, the fan means comprises at least one first fan adapted to generate a first cooling medium flow inside the first chamber between the inlet flow opening and the outlet flow opening through the first end of the at least one heat exchanger, and the cooling device is adapted to be connected to a device chamber containing a heat generating apparatus.

2. A cooling device according to claim 1, wherein the cooling device comprises a thermoelectric cooling element having a hot side and a cold side, the thermoelectric cooling element being adapted to condense moisture from the first chamber, the heat exchanger means comprises a first heat exchanger, one of the sides of the thermoelectric cooling element being in heat transfer connection with a first end of the first heat exchanger.

3. A cooling device according to claim 2, wherein the cooling device comprises pipe means adapted to carry water condensed by the thermoelectric cooling element out of the first chamber.

4. A cooling device according to claim 3, wherein the pipe means is adapted to carry water condensed by the thermoelectric cooling element into the second chamber or out of the cooling device.

5. A cooling device according to claim 2, wherein the heat exchanger means comprises a second heat exchanger adjacent the first heat exchanger, the other side of the thermoelectric cooling element being in heat transfer connection with a first end of the second heat exchanger.

6. A cooling device according to claim 1, wherein the cooling device comprises a heating element adapted to heat the first chamber; the heating element being in heat transfer connection with a first end of at least one heat exchanger.

7. A cooling device according to claim 1, wherein the at least one heat exchanger comprises at least one compact thermosyphon heat exchanger.

8. A cooling device according to claim 1, wherein the inlet flow opening and the outlet flow opening are located on the same side of the first chamber on a connection wall of the cooling device and the connection wall is a substantially planar wall for facilitating connection of the cooling device to the device chamber.

9. A cooled electrical assembly comprising a device chamber containing a heat generating apparatus, and a cooling device connected to the device chamber for cooling the heat generating apparatus, wherein the cooling device is a cooling device according to claim 1.

10. A cooled electrical assembly according to claim 9, wherein the device chamber is isolated from ambient air such that the device chamber is adapted to exchange cooling medium exclusively with the first chamber of the cooling device.

11. A cooling device according to claim 3, wherein the heat exchanger means comprises a second heat exchanger adjacent the first heat exchanger, the other side of the thermoelectric cooling element being in heat transfer connection with a first end of the second heat exchanger.

12. A cooling device according to claim 4, wherein the heat exchanger means comprises a second heat exchanger adjacent the first heat exchanger, the other side of the thermoelectric cooling element being in heat transfer connection with a first end of the second heat exchanger.

13. A cooling device according to claim 2, wherein the cooling device comprises a heating element adapted to heat the first chamber, the heating element being in heat transfer connection with a first end of at least one heat exchanger.

14. A cooling device according to claim 3, wherein the cooling device comprises a heating element adapted to heat the first chamber, the heating element being in heat transfer connection with a first end of at least one heat exchanger.

15. A cooling device according to claim 4, wherein the cooling device comprises a heating element adapted to heat the first chamber, the heating element being in heat transfer connection with a first end of at least one heat exchanger.

16. A cooling device according to claim 5, wherein the cooling device comprises a heating element adapted to heat the first chamber, the heating element being in heat transfer connection with a first end of at least one heat exchanger.

17. A cooling device according to claim 2, wherein the at least one heat exchanger comprises at least one compact thermosyphon heat exchanger.

18. A cooling device according to claim 3, wherein the at least one heat exchanger comprises at least one compact thermosyphon heat exchanger.

19. A cooling device according to claim 4, wherein the at least one heat exchanger comprises at least one compact thermosyphon heat exchanger.

20. A cooling device according to claim 5, wherein the at least one heat exchanger comprises at least one compact thermosyphon heat exchanger.
